(19) United States
(12) Patent Application Publication
(10) Pub. No.: US 2004/0262689 A1
(43) Pub. Date: Dec. 30, 2004

(54) Electrostatic discharge protection circuit

(75) Inventors: Yi-Lin Chen, Taipei (TW); An-Ming Lee, Hsinchu (TW)

Correspondence Address: BRUCE H. TROXELL, SUITE 1404, 5205 LEESBURG PIKE, FALLS CHURCH, VA, 22041, US

(73) Assignee: Realtek Semiconductor Corp.

(21) Appl. No.: 10/829,964

(22) Filed: Apr. 23, 2004

(30) Foreign Application Priority Data
Jun. 27, 2003 (TW) 92117516

(51) Int. Cl. H01L 23/62

(52) U.S. Cl. 257/355; 257/356; 361/56

(57) ABSTRACT

An electrostatic discharge protection circuit coupled between an I/O pad and an internal circuit of an IC. The electrostatic discharge protection circuit includes a first diode having a positive end coupled to the I/O pad, and a negative end coupled to a first supply voltage; a second diode having a positive end coupled to a second supply voltage, and a negative end coupled to the I/O pad; and a third diode having a positive end coupled to the second supply voltage, and a negative end coupled to the first-supply voltage. The breakdown voltage of the third diode is substantially smaller than the breakdown voltage of the first diode or the breakdown voltage of the second diode.

### FIELD OF THE INVENTION

The present invention relates to an electrostatic discharge protection circuit, more particularly, to an electrostatic discharge protection circuit arranged between an internal circuit and signal input/output pads of an integrated circuit.

### BACKGROUND OF THE INVENTION

Electrostatic discharge (ESD) phenomenon has become a growing problem for integrated circuit designers and manufacturers because of the frequent damage caused by ESD to internal circuits of ICs, by way of either I/O pads or power supply pins, especially when the size of devices in ICs are getting smaller and smaller. As a result, electrostatic discharge protection circuits are adopted to minimize the destructive effect of ESD on ICs.

Please refer to FIG. 1A, which illustrates a schematic circuit diagram of a conventional ESD protection circuit 120. The ESD protection circuit 120 is disposed between an internal circuit 100 of an IC and a signal input/output pad 110. The I/O pad 110 is used for inputting and/or outputting signals to/from the internal circuit 100 of the IC. The ESD protection circuit 120 typically comprises a diode 130a coupled between a node A and a power supply V_{DD}, and a diode 140a coupled between the node a and ground GND, as shown in FIG. 1B, which usually are realized by a diode-connected PMOS transistor 130 and a diode-connected NMOS transistor 140, as shown in FIG. 1A, respectively.

The ESD protection circuit 120 of FIGS. 1A and 1B takes advantage of the forward bias operations and/or reverse bias operations of the diodes 130a, 140a, to pass excess current to V_{DD} or ground when the I/O pad 110 encounters ESD, so as to protect the internal circuit 100 of the IC. Among which, it is usually the reverse bias operations of the diodes 130a, 140a that construes a bottleneck of the performance of the ESD protection circuit 120, because it is likely that the diodes 130a, 140a may fry during the reverse bias operations. As a result, large-sized (i.e., large aspect ratio) devices are adopted in constructing the ESD protection circuit 120 to overcome such bottleneck. However, large-sized devices translate to large die size and large parasitic capacitance, which eventually hurt the cost and high-speed performance of the IC.

To solve this dilemma, a number of approaches have been taken in the related art. Please refer to FIG. 2A, which shows a schematic circuit diagram of such an approach. The ESD protection circuit 200 of FIG. 2A utilizes a well-known PESD technology in fabricating the NMOS transistor 140, which is detailed in a side-view physical structure diagram in FIG. 2B. In FIG. 2B a P⁺ region 210 is implanted in the vicinity of the drain of the NMOS transistor 140. As is known to those skilled in the art, the PESD approach can render a more robust NMOS diode during reverse bias operations without a large aspect ratio.

Another such approach can be found in U.S. Pat. No. 5,744,842, “Area-Efficient VDD-to-VSS ESD Protection Circuit” by Ker, which is incorporated herein by reference. Besides of two series connected diode devices, Ker adopts an N-type field oxide device together with an ESD-transient detection circuit, which includes a resistor, a capacitor, and an inverter. The circuitry suggested therein provides an additional current path through the field oxide device connected between VDD and VSS when ESD phenomenon occurs. However, the inclusion of the resistor and the capacitor in the circuitry not only consumes a relatively large die area, the tuning of R-C time constant also increases design complexity.

### SUMMARY OF THE INVENTION

It is therefore one of the many objectives of the present invention to provide an electrostatic discharge protection circuit which is suitable for high-speed application.

According to an embodiment of the invention, an electrostatic discharge protection circuit coupled between an I/O pad and an internal circuit of an IC is disclosed. The electrostatic discharge protection circuit comprises a first diode having a positive end coupled to the I/O pad, and a negative end coupled to a first supply voltage; a second diode having a positive end coupled to a second supply voltage, and a negative end coupled to the I/O pad; and a third diode having a positive end coupled to the second supply voltage, and a negative end coupled to the first supply voltage. The breakdown voltage of the third diode is substantially smaller than the breakdown voltage of the first diode.

According to an embodiment of the invention, an electrostatic discharge protection circuit coupled between an I/O pad and an internal circuit of an IC is also disclosed. The electrostatic discharge protection circuit comprises a first diode having a positive end coupled to the I/O pad, and a negative end coupled to a first supply voltage; a second diode having a positive end coupled to a second supply voltage, and a negative end coupled to the I/O pad; and a third diode having a positive end coupled to the second supply voltage, and a negative end coupled to the first supply voltage. The breakdown voltage of the third diode is substantially smaller than the breakdown voltage of the second diode.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a schematic diagram showing a conventional electrostatic discharge protection circuit.

FIG. 1B is an equivalent circuitry of FIG. 1A.

FIG. 2A is a schematic diagram showing another conventional electrostatic discharge protection circuit.

FIG. 2B is a diagram depicting a side view physical structure of a NMOS transistor with PESD implantation.

FIG. 3A is a schematic diagram showing an electrostatic discharge protection circuit according to an embodiment of the present invention.

FIG. 3B is a diagram depicting a side view physical structure of a field oxide device according to an embodiment of the invention.

FIG. 4A, FIG. 4B, FIG. 4C, FIG. 4D respectively illustrate four operating situations of the ESD protection circuit in FIG. 3A.

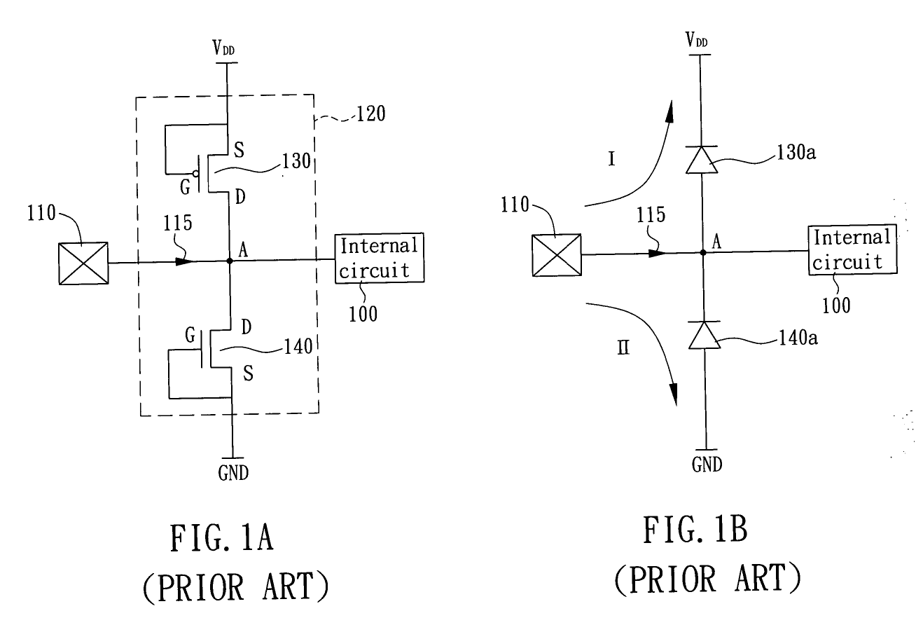

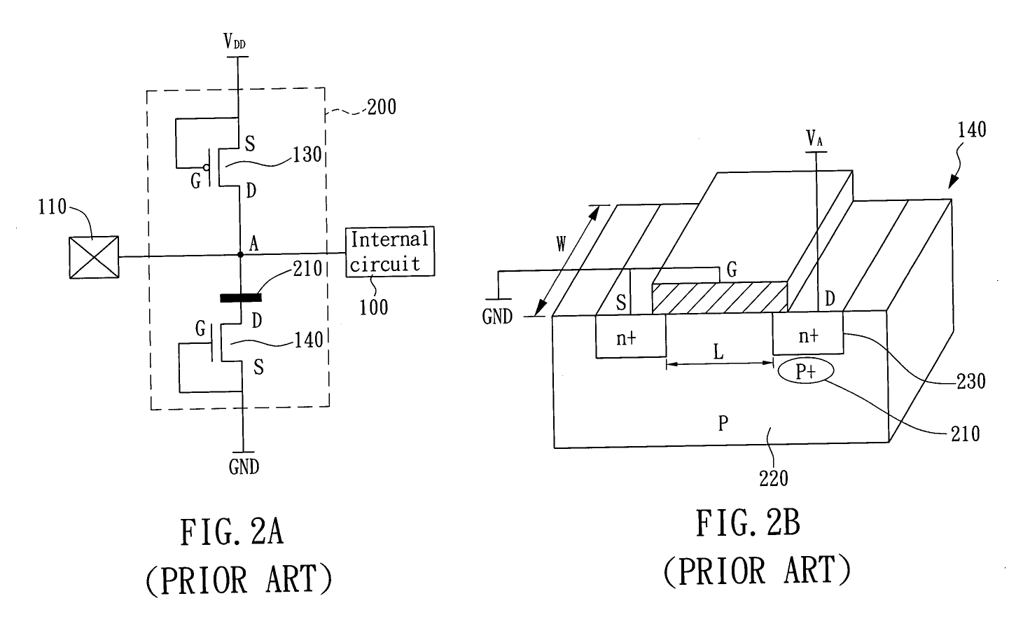

### DESCRIPTION OF THE PREFERRED EMBODIMENT

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

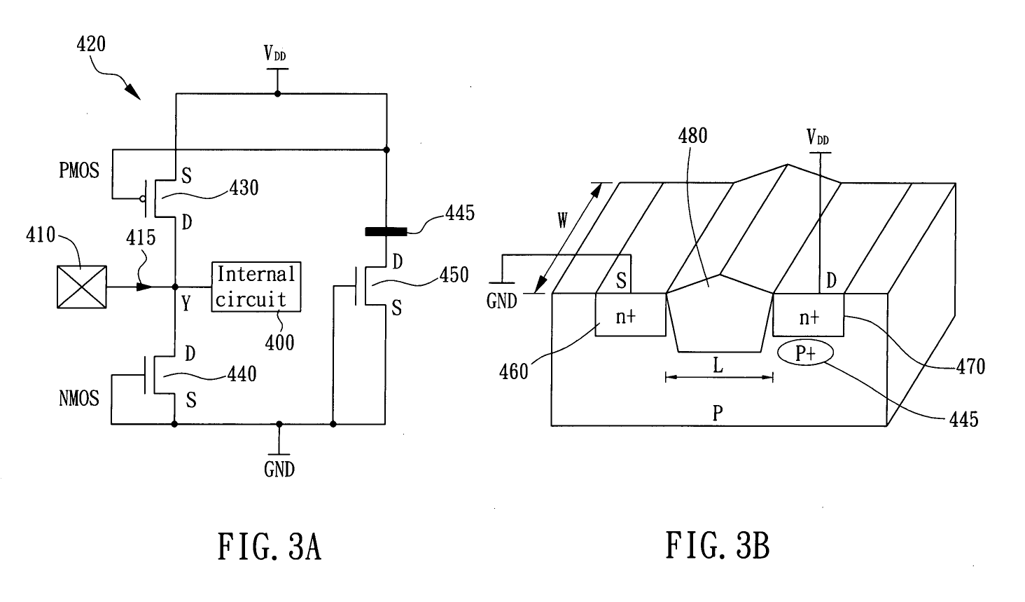

Please refer to FIG. 3A, which is a schematic diagram showing an electrostatic discharge protection circuit according to an embodiment of the present invention. The ESD protection circuit 420 is disposed between an internal circuit 400 and an I/O pad 410 of an IC, for protecting the internal circuit 400 of the IC from potential damage caused by ESD. The ESD protection circuit 420 comprises a first diode device and a second diode device, which in this embodiment are implemented by a diode-connected PMOS transistor 430 and a diode-connected NMOS transistor 440, respectively. The ESD protection circuit 420 also comprises a third diode device, which in this embodiment is implemented by a diode-connected NMOS transistor 450 with PESD implantation 445, as shown in FIG. 3A. Please note that by utilizing the PESD implantation 445, the breakdown voltage of the P-N junction of the third diode device may be substantially smaller than that of the first diode device. Similarly, the breakdown voltage of the P-N junction of the third diode device may also be substantially smaller than that of the second diode device.

It is appreciated by those with ordinary skill in the art that although NMOS transistor 450 with PESD technology is applied in this embodiment, there are other embodiments which can serve to obtain a smaller breakdown voltage in the P-N junction of the third diode device. One of these embodiments is by substituting the NMOS transistor 450 in FIG. 3A with a field oxide device as illustrated in FIG. 3B, which is well-known to those skilled in the art. The field oxide device is formed by coupling two n+ regions 460, 470 to the ground and the supply voltage VDD, respectively, with an isolating field oxide region 480 disposed therebetween, and a PESD implantation beneath the n+ region 470. The width L of the field oxide region 480 may be properly adjusted such that the ESD protection circuit can take advantage of the current draining capability of a parasitic bipolar device in the field oxide device.

Please refer to FIG. 3A, which is a schematic diagram showing an electrostatic discharge protection circuit according to an embodiment of the present invention. The internal circuit 400 of an IC use the I/O pad 410 for transferring high frequency signals 415, and an electrostatic discharge protection circuit 420 disposed between the I/O pad 410 and the internal circuit 400 is consisted of a PMOS transistor 430, a NMOS transistor 440 and a NMOS transistor 450 with a P⁺ region 445 formed in the vicinity of the drain thereof.

Other embodiments also include using low-voltage devices with shallower junction region in the third diode device comparing to the first or second diode device, so as to lower the breakdown voltage of the third diode device, or utilizing low-density doping in the first or second diode device to raising the breakdown voltage thereof, so as to render a smaller breakdown voltage of the third diode device than that of the first or second diode device. The above-mentioned techniques are well-known to those with ordinary skill in the art, and are thus not detailed herein.

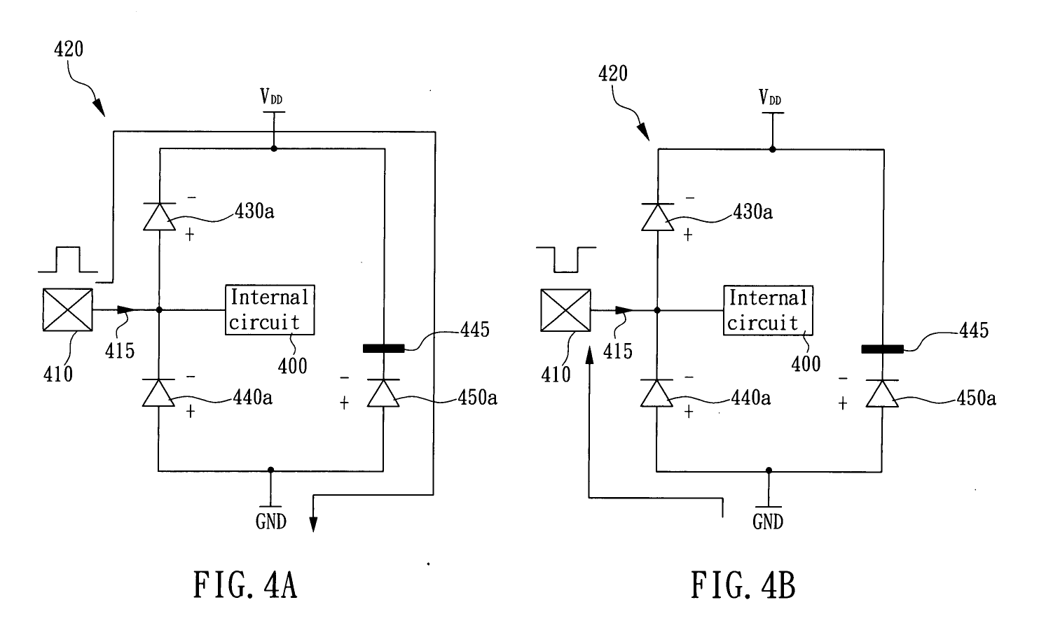

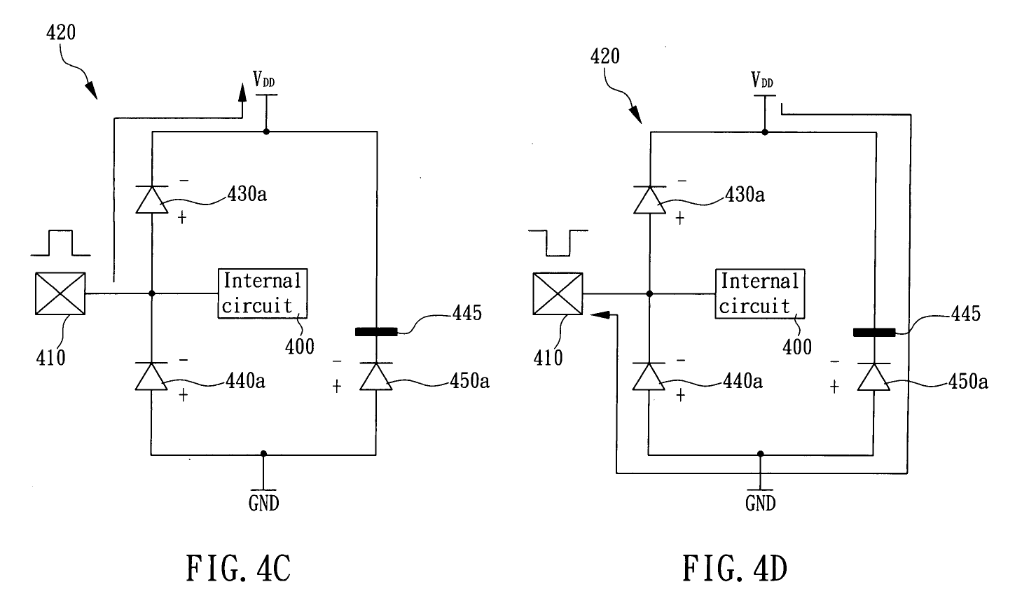

To further make clear the operations of the ESD protection circuit 420 in FIG. 3A according to embodiments of the present invention, please consider the following four situations accompanying illustrative diagrams FIG. 4A, 4B, 4C, and 4D. In FIG. 4A, when the ESD phenomenon occurs causing an instantaneous positive pulse between the I/O pad 410 and the ground GND, because the breakdown voltage of the third diode device 450a is smaller than that of the second diode device 440a, the excess current resulted from such ESD phenomenon tends to pass through a discharge path formed by the forward-biased first diode device 430a and the reverse-biased third diode device 450a to GND, as shown by the arrowhead in FIG. 4A, rather than a discharge path formed by the reverse-biased second diode device 440a.

In FIG. 4B, when the ESD phenomenon occurs causing an instantaneous negative pulse between the I/O pad 410 and the ground GND, the excess current resulted from such ESD phenomenon tends to pass through a discharge path formed by the forward-biased second diode device 440a to GND, as shown by the arrowhead in FIG. 4B, rather than a discharge path formed by the forward-biased third diode device 450a and the reverse-biased first diode device 430a.

In FIG. 4C, when the ESD phenomenon occurs causing an instantaneous positive pulse between the I/O pad 410 and the supply voltage VDD, the excess current resulted from such ESD phenomenon tends to pass through a discharge path formed by the forward-biased first diode device 430a to VDD, as shown by the arrowhead in FIG. 4C, rather than a discharge path formed by the reverse-biased second diode device 440a and the forward-biased third diode device 450a.

In FIG. 4D, when the ESD phenomenon occurs causing an instantaneous negative pulse between the I/O pad 410 and the supply voltage VDD, because the breakdown voltage of the third diode device 450a is smaller than that of the first diode device 430a, the excess current resulted from such ESD phenomenon tends to pass through a discharge path formed by the reverse-biased third diode device 450a and the forward-biased second diode device 440a to VDD, as shown by the arrowhead in FIG. 4D, rather than a discharge path formed by the reverse-biased first diode device 430a.

While the embodiments of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An electrostatic discharge protection circuit coupled between an I/O pad and an internal circuit of an IC, the electrostatic discharge protection circuit comprising:
a first diode having a positive end coupled to the I/O pad, and a negative end coupled to a first supply voltage;
a second diode having a positive end coupled to a second supply voltage, and a negative end coupled to the I/O pad; and
a third diode having a positive end coupled to the second supply voltage, and a negative end coupled to the first supply voltage;
wherein the breakdown voltage of the third diode is substantially smaller than the breakdown voltage of the first diode.

2. The electrostatic discharge protection circuit of claim 1, wherein the first diode is a diode-connected PMOS transistor.

3. The electrostatic discharge protection circuit of claim 1, wherein the second diode is a diode-connected NMOS transistor.

4. The electrostatic discharge protection circuit of claim 1, wherein the third diode is a diode-connected NMOS transistor.

5. The electrostatic discharge protection circuit of claim 4, wherein the NMOS transistor of the third diode has a P⁺ region implanted under the drain region of the NMOS transistor.

6. The electrostatic discharge protection circuit of claim 4, wherein the NMOS transistor of the third diode is a low-voltage device compared to the first diode.

7. The electrostatic discharge protection circuit of claim 1, wherein the first diode has a lower doping density than the third diode.

8. The electrostatic discharge protection circuit of claim 1, wherein the third diode is a field oxide device.

9. An electrostatic discharge protection circuit coupled between an I/O pad and an internal circuit of an IC, the electrostatic discharge protection circuit comprising:
a first diode having a positive end coupled to the I/O pad, and a negative end coupled to a first supply voltage;
a second diode having a positive end coupled to a second supply voltage, and a negative end coupled to the I/O pad; and
a third diode having a positive end coupled to the second supply voltage, and a negative end coupled to the first supply voltage;
wherein the breakdown voltage of the third diode is substantially smaller than the breakdown voltage of the second diode.

10. The electrostatic discharge protection circuit of claim 9, wherein the first diode is a diode-connected PMOS transistor.

11. The electrostatic discharge protection circuit of claim 9, wherein the second diode is a diode-connected NMOS transistor.

12. The electrostatic discharge protection circuit of claim 9, wherein the third diode is a diode-connected NMOS transistor.

13. The electrostatic discharge protection circuit of claim 12, wherein the NMOS transistor of the third diode has a P⁺ region implanted under the drain region of the NMOS transistor.

14. The electrostatic discharge protection circuit of claim 12, wherein the NMOS transistor of the third diode is a low-voltage device compared to the second diode.

15. The electrostatic discharge protection circuit of claim 9, wherein the second diode has a lower doping density than the third diode.

16. The electrostatic discharge protection circuit of claim 9, wherein the third diode is a field oxide device.
